(19) United States
(12) Patent Application Publication
(10) Pub. No.: US 2025/0208230 A1
(43) Pub. Date: Jun. 26, 2025

(54) BATTERY MANAGEMENT SYSTEM, MEMORY, DISPLAY METHOD, AND STORAGE MEDIUM INCLUDING DISPLAY PROGRAM

(71) Applicant: DENSO CORPORATION, Kariya-city (JP)

(72) Inventors: Hiroki FUJII, Kariya-city (JP); Shuhei YOSHIDA, Kariya-city (JP)

(21) Appl. No.: 19/075,632

(22) Filed: Mar. 10, 2025

Related U.S. Application Data
(63) Continuation of application No. PCT/JP2023/033394, filed on Sep. 13, 2023.

(30) Foreign Application Priority Data
Oct. 10, 2022 (JP) 2022-162849

(51) Int. Cl. G01R 31/392; B60L 58/16; G01R 31/36; G01R 31/367; G01R 31/374; G01R 31/3842

(52) U.S. Cl. CPC G01R 31/392; B60L 58/16; G01R 31/3646; G01R 31/367; G01R 31/374; G01R 31/3842; B60L 2240/662

(57) ABSTRACT

A battery management system includes an obtaining unit, an estimating unit, and a display. The obtaining unit obtains electrical data of a battery in an operating state of a monitoring unit that monitors the battery, and environmental data in a non-operating state. The electrical data includes a first SOC of the battery before transition from the operating state to the non-operating state and a second SOC of the battery after transition from the non-operating state to the operating state. The environmental data includes an outside temperature. The estimating unit estimates a charge/discharge state in the non-operating state based on the first SOC and the second SOC, estimates a temperature of the battery in the non-operating state based on the outside temperature, and estimates the degradation degree of the battery in the non-operating state based on the estimated charge and discharge state and the estimated temperature of the battery.

### CROSS REFERENCE TO RELATED APPLICATIONS

The present application is a continuation application of International Patent Application No. PCT/JP2023/033394 filed on Sep. 13, 2023, which designated the U.S. and claims the benefit of priority from Japanese Patent Application No. 2022-162849 filed on Oct. 10, 2022. The entire disclosures of all the above applications are incorporated herein by reference.

### TECHNICAL FIELD

The present disclosure relates to a battery management system, a memory, a display method, and a storage medium including a display program.

### BACKGROUND

There is a state determination system which includes an obtaining unit and a diagnosis unit. The obtaining unit obtains physical quantity data related to a battery, and the diagnosis unit diagnoses a degradation degree of the battery based on the physical quantity data.

### SUMMARY

According to a first aspect, a battery management system for a battery in a mobile object includes an obtaining unit, an estimating unit, and a display. The obtaining unit obtains electrical data related to an electrical state of the battery in an operating state of a monitoring unit that monitors the battery, and environmental data related to an environment of the battery in a non-operating state of the monitoring unit. The estimating unit estimates, based on the electrical data and the environmental data, a degradation degree of the battery in the non-operating state of the monitoring unit. The display displays the estimated degradation degree of the battery. The electrical data includes a first SOC of the battery at a time before the monitoring unit transitions from the operating state to the non-operating state, and a second SOC of the battery at a time after the monitoring unit transitions from the non-operating state to the operating state. The environmental data includes an outside temperature outside the mobile object in the non-operating state of the monitoring unit. The estimating unit estimates a charge and discharge state of the battery in the non-operating state of the monitoring unit based on the first SOC and the second SOC, estimates a temperature of the battery in the non-operating state of the monitoring unit based on the outside temperature in the non-operating state, and estimates the degradation degree of the battery in the non-operating state based on the estimated charge and discharge state and the estimated temperature of the battery.

According to a second aspect, a memory is included in the battery management system. The memory stores the electrical data related to the electrical state of the battery in the operating state of the monitoring unit, and the environmental data related to the environment of the battery in the non-operating state of the monitoring unit.

According to a third aspect, a display method is used in the battery management system. The display method includes displaying, on a display, the degradation degree of the battery and at least one of the electrical data related to the electrical state of the battery in the operating state of the monitoring unit or the environmental data related to the environment of the battery in the non-operating state of the monitoring unit.

According to a fourth aspect, a storage medium is included in the battery management system. The storage medium stores a display program that is configured to cause a processor to display, on a display, the degradation degree of the battery and at least one of the electrical data related to the electrical state of the battery in the operating state of the monitoring unit or the environmental data related to the environment of the battery in the non-operating state of the monitoring unit.

### BRIEF DESCRIPTION OF THE DRAWINGS

The above and other objects, features and advantages of the present disclosure will be more clearly understood from the following detailed description with reference to the accompanying drawings. In the accompanying drawings:

FIG. 1 is a diagram illustrating a battery management system according to a first embodiment;

FIG. 2 is a diagram showing data used for battery state diagnosis with respect to the operating state of a mobile object;

FIG. 3 is a flowchart showing the contents of the battery state diagnosis;

FIG. 4 is a diagram for explaining a method for estimating a current value when the charge and discharge state of a battery is obtainable;

FIG. 5 is a diagram showing the behavior of an actual current value and an SOC when the charge and discharge state of the battery is not obtainable;

FIG. 6 is a diagram for explaining a method for estimating a current value and an SOC when the charge and discharge state of the battery is not obtainable;

FIG. 7 is a diagram for explaining a method for estimating a current value and an SOC when the charge and discharge state of the battery is not obtainable;

FIG. 8 is a diagram illustrating a battery management system according to a second embodiment;

FIG. 9 is a diagram illustrating a battery management system according to a third embodiment; and

FIG. 10 is a diagram illustrating a battery management system according to a fourth embodiment.

### DETAILED DESCRIPTION OF THE PREFERRED EMBODIMENTS

To begin with, examples of relevant techniques will be described.

There is a state determination system which includes an obtaining unit and a diagnosis unit. The obtaining unit obtains physical quantity data indicating physical quantities related to the state of a battery that is chargeable and dischargeable. The diagnosis unit diagnoses a degradation degree of the battery based on the physical quantity data.

However, the above-mentioned technology is based on the premise that physical quantity data is obtained by the obtaining unit that monitors the battery. That is, the obtaining unit needs to operate for diagnosing the degradation degree of the battery. Thus, the user may not recognize the degradation degree of the battery when the obtaining unit is not operating.

In view of the above, it is an objective of the present disclosure to provide a battery management system, a memory, a display method, and a storage medium including a display program that allow a user to recognize the degradation degree of a battery when a monitoring unit that monitors the battery is not operating.

According to a first aspect of the present disclosure, a battery management system for a battery in a mobile object includes an obtaining unit, an estimating unit, and a display. The obtaining unit obtains electrical data related to an electrical state of the battery in an operating state of a monitoring unit that monitors the battery, and environmental data related to an environment of the battery in a non-operating state of the monitoring unit. The estimating unit estimates, based on the electrical data and the environmental data, a degradation degree of the battery in the non-operating state of the monitoring unit. The display displays the estimated degradation degree of the battery. The electrical data includes a first SOC of the battery at a time before the monitoring unit transitions from the operating state to the non-operating state, and a second SOC of the battery at a time after the monitoring unit transitions from the non-operating state to the operating state. The environmental data includes an outside temperature outside the mobile object in the non-operating state of the monitoring unit. The estimating unit estimates a charge and discharge state of the battery in the non-operating state of the monitoring unit based on the first SOC and the second SOC, estimates a temperature of the battery in the non-operating state of the monitoring unit based on the outside temperature in the non-operating state, and estimates the degradation degree of the battery in the non-operating state based on the estimated charge and discharge state and the estimated temperature of the battery.

According to a second aspect of the present disclosure, a memory included in the battery management system is provided. The battery management system displays to a user a degradation degree of a battery in a mobile object in a non-operating state of a monitoring unit that monitors the battery. The memory stores electrical data relating to an electrical state of the battery in an operating state of the monitoring unit, and environmental data relating to an environment of the battery in the non-operating state of the monitoring unit.

According to a third aspect of the present disclosure, a display method is used in the battery management system that displays to a user a degradation degree of a battery in a mobile object in a non-operating state of a monitoring unit that monitors the battery. The display method includes displaying the degradation degree of the battery and at least one of electrical data related to an electrical state of the battery in an operating state of the monitoring unit, or environmental data related to an environment of the battery in the non-operating state of the monitoring unit.

According to a fourth aspect of the present disclosure, a storage medium including a display program is included in the battery management system that displays to a user a degradation state of a battery in a mobile object during a non-operating state of a monitoring unit that monitors the battery. The display program is configured to cause a processor to display on a display the degradation degree of the battery and at least one of electrical data related to an electrical state of the battery in an operating state of the monitoring unit, or environmental data related to an environment of the battery in the non-operating state of the monitoring unit.

This allows the user to recognize the degradation state of the battery when the monitoring unit is not operating.

The following describe embodiments for carrying out the present disclosure with reference to the drawings. In each embodiment, parts corresponding to the elements described in the preceding embodiments are denoted by the same reference numerals, and redundant explanation may be omitted. When only a part of the configuration is described in each embodiment, another embodiment described previously may be applied to the other parts of the configuration.

When, in each embodiment, it is specifically described that combination of parts is possible, the parts can be combined. In a case where any obstacle does not especially occur in combining the parts of the respective embodiments, it is possible to partially combine the embodiments, the embodiment and the modification, or the modifications even when it is not explicitly described that combination is possible.

### First Embodiment

A battery management system displays to a user the degradation degree of a battery installed in a mobile object, specifically the degradation degree when a monitoring unit that monitors the battery is not operating. The battery management system can also display to the user the degradation degree of the battery when the monitoring unit is operating.

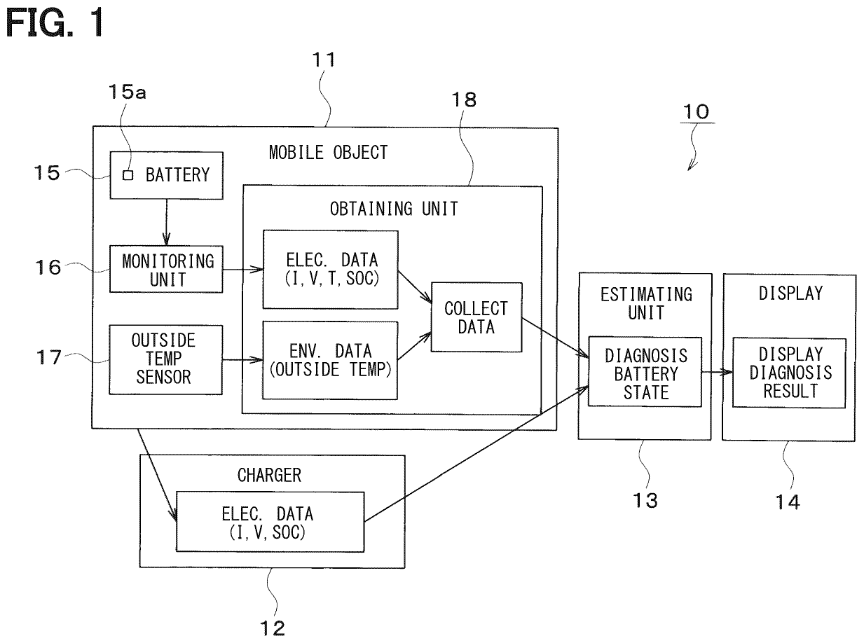

A first embodiment will be described with reference to the drawings. As shown in FIG. 1, the battery management system 10 according to the present embodiment includes a mobile object 11, a charger 12, an estimating unit 13, and a display 14.

The mobile object 11 is equipped with a battery 15 and can move using the battery 15 as a power source. The mobile object 11 is, for example, an electric vehicle such as an electric car or a hybrid car, an electric two-wheeled vehicle such as an electric bicycle or an electric motorcycle, a small unmanned aerial vehicle, an electric air mobility, a train, and a ship. In this embodiment, the mobile object 11 is an electric vehicle.

The battery 15 is a rechargeable secondary battery. The battery 15 constitutes a battery module in which multiple battery cells are connected in series. Each battery cell is, for example, a lithium ion secondary battery. The battery 15 is provided with a monitoring sensor 15a. The monitoring sensor 15a includes a current sensor, a voltage sensor, a temperature sensor, and the like. These sensors detect the current, voltage, and temperature of the battery 15 at any time.

In addition to the battery 15, the mobile object 11 includes a monitoring unit 16, an outside temperature sensor 17, and an obtaining unit 18. The monitoring unit 16 is a device for monitoring and controlling the battery 15 when operating. When the monitoring unit 16 is operating means when the mobile object 11 is operating and when in-vehicle communication is operating. When the in-vehicle communication is operating, the monitoring unit 16 and the obtaining unit 18 are connected with each other through the in-vehicle communication. For example, when the ignition switch of the mobile object 11 is on (i.e., IGON) corresponds to when the in-vehicle communication is operating.

The monitoring unit 16 is, for example, a Battery Management Unit (i.e., BMU). The monitoring unit 16 reads data on the current, voltage, and temperature of the battery 15 from the sensors provided in the battery 15 when operating. In addition, the monitoring unit 16 calculates the State Of Charge (i.e., SOC) of the battery 15 based on the data obtained from the battery 15.

The monitoring unit 16 in operation outputs, to the obtaining unit 18, the data on the current, voltage, and temperature of the battery 15 obtained from the battery 15 and the calculated SOC based on instructions from the obtaining unit 18. The current (I), voltage (V), temperature (T), and SOC of the battery 15 are electrical data related to the electrical state of the battery 15.

The monitoring unit 16 is not limited to a BMU, and may be another device capable of monitoring the battery 15. Furthermore, the monitoring unit 16 does not need to calculate the SOC. The calculation of the SOC may be performed downstream of the monitoring unit 16 in the information transmission. For example, the estimating unit 13 may calculate the SOC.

The outside temperature sensor 17 is a sensor that measures the temperature (TE) outside the mobile object 11. The outside temperature (TE) of the mobile object 11 is the temperature around the mobile object 11. The outside temperature is environmental data related to the environment of the battery 15. In this embodiment, the outside temperature sensor 17 measures the temperature (TE) outside the mobile object 11.

The outside temperature sensor 17 measures the outside temperature (TE) outside the mobile object 11 not only when the monitoring unit 16 is operating, but also when the monitoring unit 16 is not operating. The period when the monitoring unit 16 is not operating refers to the period when the in-vehicle communication of the mobile object 11 is not operating. That is, when the in-vehicle communication is not operating, the in-vehicle communication between the monitoring unit 16 and the obtaining unit 18 is interrupted. For example, the period during the ignition of the mobile object 11 is off (i.e., IGOFF) corresponds to the period when the in-vehicle communication is not operating.

The obtaining unit 18 obtains electrical data of the battery 15, specifically the electrical data when the monitoring unit 16 is operating. The electrical data includes a first SOC of the battery 15 and a second SOC of the battery 15. The first SOC is the SOC before the monitoring unit 16 transitions from the operating state to the non-operating state. The second SOC of the battery 15 is the SOC after the monitoring unit 16 transitions from the non-operating state to the operating state.

In addition, the obtaining unit 18 obtains environmental data of the battery 15 regardless of whether the monitoring unit 16 is operating or not. The obtaining unit 18 can obtain environmental data from the outside temperature sensor 17 not only when the monitoring unit 16 is operating, but also when the monitoring unit 16 is not operating. For example, the obtaining unit 18 and the outside temperature sensor 17 are connected by wire. Thus, even when the monitoring unit 16 is not operating, the obtaining unit 18 can obtain environmental data from the outside temperature sensor 17. The environmental data includes the outside temperature (TE) outside the mobile object 11 when the monitoring unit 16 is not operating.

The obtaining unit 18 collects electrical data and environmental data from the monitoring unit 16 and the outside temperature sensor 17, and outputs the data to the estimating unit 13 by using wireless communication such as Long-Term Evolution (i.e., LTE). The obtaining unit 18 may output the data to the estimating unit 13 via a wired connection rather than wireless connection. Furthermore, the obtaining unit 18 may or may not have a function for recording electrical data and environmental data.

Alternatively, the obtaining unit 18 may store and preserve the electrical data and the environmental data. In this case, the obtaining unit 18 corresponds to a memory that stores electrical data related to the electrical state of the battery 15 when the monitoring unit 16 is operating, and environmental data related to the environment of the battery 15 when the monitoring unit 16 is not operating.

When the obtaining unit 18 serves as a memory, the obtaining unit 18 stores electrical data at a time when the monitoring unit 16 transitions from the operating state to the non-operating state, electrical data at a time when the monitoring unit 16 transitions from the non-operating state to the operating state, and sequential environmental data in the non-operating state of the monitoring unit 16. The electrical data includes the SOC of the battery 15, and the environmental data includes the outside temperature (TE) outside the mobile object 11. The obtaining unit 18 may store environmental data in the operating state of the monitoring unit 16.

The charger 12 is a device for charging the battery 15. When a charging cable of the charger 12 is connected to the mobile object 11, the battery 15 can be charged. The charger 12 obtains the current SOC of the battery 15 from the mobile object 11. The charger 12 converts alternating current supplied from an external power source into direct current based on the obtained SOC, and supplies the direct current to the battery 15. Thus, the battery 15 is charged.

The charging of the battery 15 by the charger 12 may be performed wirelessly instead of via a wire. The charger 12 and the mobile object 11 may exchange electrical signals with each other through a wire communication or a wireless communication.

The charger 12 obtains information on not only the SOC but also the current and voltage of the battery 15 from the mobile object 11. The charger 12 wirelessly transmits the obtained electrical data of the obtained current (I), voltage (V), and SOC to the estimating unit 13. The charger 12 outputs the electrical data to the estimating unit 13 using a communication protocol such as Open Charge Point Protocol (OCPP). The charger 12 may output the data to the estimating unit 13 via a wired connection instead of a wireless connection.

The charger 12 also includes a bidirectional charger. The bidirectional charger can charge the battery 15 and extract power from the battery 15. That is, the battery 15 can be discharged.

The estimating unit 13 and the display 14 are disposed in a location different from the mobile object 11 and the charger 12. The estimating unit 13 is arranged in, for example, cloud computing. The electrical data and environmental data transmitted from the mobile object 11 and the charger 12 are stored in the cloud.

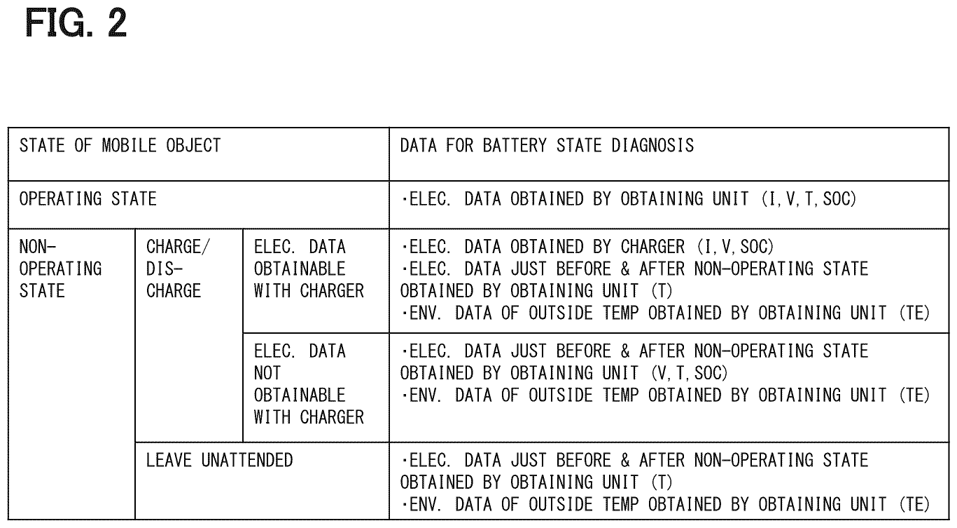

The estimating unit 13 diagnoses the state of the battery. That is, the estimating unit 13 estimates the degradation degree of the battery 15 based on the electrical data and environmental data stored in the cloud. Specifically, as shown in FIG. 2, the estimating unit 13 switches data used for the battery state diagnosis depending on the operating state of the mobile object 11. When the monitoring unit 16 is operating, the estimating unit 13 estimates the degradation degree of the battery 15 in the operating state of the monitoring unit 16 based on the electrical data of current (I), voltage (V), temperature (T), and SOC obtained by the obtaining unit 18.

When the electrical data and the environmental data are stored in the estimating unit 13, the estimating unit 13 corresponds to a memory that stores electrical data related to the electrical state of the battery 15 in the operating state of the monitoring unit 16, and environmental data related to the environment of the battery 15 in the non-operating state of the monitoring unit 16.

When the estimating unit 13 serves as a memory, the estimating unit 13 stores electrical data at a time before the monitoring unit 16 transitions from the operating state to the non-operating state, electrical data at a time after the monitoring unit 16 transitions from the non-operating state to the operating state, and sequential environmental data in the non-operating state of the monitoring unit 16. The electrical data includes the SOC of the battery 15 and the environmental data includes the outside temperature (TE) outside the mobile object 11. The estimating unit 13 may store environmental data in the operating state of the monitoring unit 16.

In contrast, when the electrical data and the environmental data are stored in a storage area different from the estimating unit 13, the storage area different from the estimating unit 13 corresponds to the memory that stores the electrical data and the environmental data.

When the monitoring unit 16 is not operating, the battery 15 may be charged or discharged, or the mobile object 11 may be left unattended. When the battery 15 is charged or discharged, there are cases where the charger 12 can obtain electrical data or not.

When the charger 12 can obtain electrical data, the estimating unit 13 estimates the degradation degree of the battery 15 in the non-operating state of the monitoring unit 16 based on the electrical data of current (I), voltage (V), and SOC obtained by the charger 12, the electrical data of the temperature (T) of the battery 15 obtained by the monitoring unit 16 in operation at times immediately preceding and subsequent to the non-operating state of the monitoring unit 16, and the environmental data of the outside temperature (TE) outside the mobile object 11 obtained by the obtaining unit 18. The times immediately preceding and subsequent to the non-operating state of the monitoring unit 16 indicate the time immediately before the monitoring unit 16 switches from the operating state to the non-operating state and the time immediately after the monitoring unit 16 switches from the non-operating state to the operating state.

Examples of cases in which the charger 12 cannot obtain electrical data include cases in which the battery 15 is charged using a device that cannot obtain electrical data, such as an alternating current outlet, instead of the charger 12, and cases in which the battery 15 is charged using a charger 12 that is not capable of obtaining electrical data. When the charger 12 cannot obtain electrical data, the estimating unit 13 estimates the degradation degree of the battery 15 in the non-operation state of the monitoring unit 16 based on the electrical data obtained by the monitoring unit 16 at times immediately preceding and subsequent to the non-operating state, and the environmental data obtained by the obtaining unit 18. The electrical data includes the voltage (V), temperature (T), and SOC. The environmental data includes the outside temperature (TE) outside the mobile object 11.

The term “left unattended” refers to a situation in which the mobile object 11 is not in use and the battery 15 is not being charged or discharged. For example, such situation includes when the mobile object 11 is parked. When the mobile object 11 is left unattended, the estimating unit 13 estimates the degradation degree of the battery 15 in the non-operating state of the monitoring unit 16 based on the electrical data of the temperature (T) obtained by the monitoring unit 16 in operation at times immediately preceding and subsequent to the non-operating state of the monitoring unit 16, and environmental data of the outside temperature (TE) outside the mobile object 11 obtained by the obtaining unit 18.

The estimating unit 13 calculates (estimates) the current degradation degree of the battery 15 by integrating the degradation degree of the battery 15 from the initial state to the current state of the battery 15. The degradation degree of the battery 15 includes not only the degradation of the battery 15 when the monitoring unit 16 is operating, but also the degradation of the battery 15 when the monitoring unit 16 is not operating. The estimating unit 13 outputs the degradation degree of the battery 15 to the display 14.

The display 14 outputs the diagnosis result of the estimating unit 13. That is, the display 14 displays the degradation degree of the battery 15 acquired by the estimating unit 13 to the user. The degradation degree of the battery 15 displayed on the display 14 includes the degradation degree of the battery 15 when the monitoring unit 16 is not operating. The display 14 is, for example, a portable information terminal of the user.

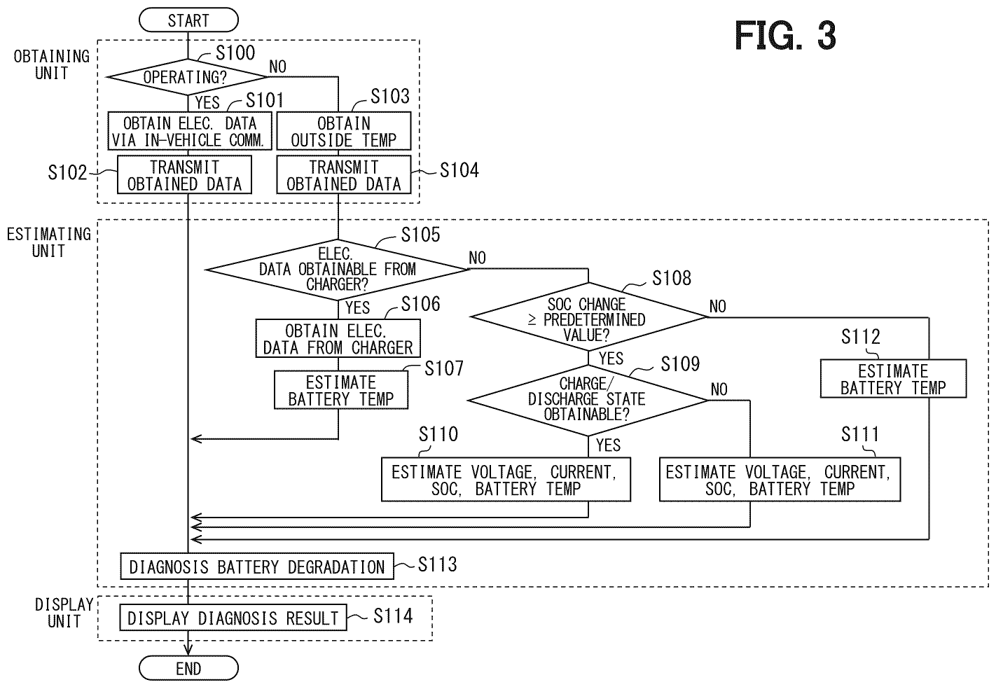

Next, the battery state diagnosis when the monitoring unit 16 is in operation and when the monitoring unit 16 is not in operation will be described with reference to the flowchart of FIG. 3. The flowchart of FIG. 3 is repeated as long as the battery 15 remains in use without being discarded.

First, steps S100 to S104 are executed by the obtaining unit 18 of the mobile object 11. In step S100, it is determined whether the mobile object 11 is operating. That is, it is determined whether the in-vehicle communication is operating. If the mobile object 11 is operating, the obtaining unit 18 moves the process to step S101.

In step S101, electrical data is obtained through in-vehicle communication. That is, the obtaining unit 18 obtains the electrical data of the battery 15, such as the current (I), voltage (V), temperature (T), and SOC, obtained by the monitoring unit 16 from the monitoring unit 16 via in-vehicle communication. In step S102, the obtaining unit 18 transmits the obtained electrical data to the estimating unit 13.

If it is determined in step S100 that the mobile object 11 is not operating, the obtaining unit 18 moves the process to step S103. In step S103, the obtaining unit 18 obtains the outside temperature (TE) outside the mobile object 11 as environmental data. In step S104, the obtaining unit 18 transmits the obtained environmental data to the estimating unit 13, similarly to step S102.

Subsequently, steps S105 to S113 are executed by the estimating unit 13 in the cloud. In step S105, it is determined whether electrical data is obtainable from the charger 12. That is, it is determined whether electrical data is currently being transmitted from the charger 12 to the cloud.

When it is determined that electrical data is obtainable from the charger 12, the estimating unit 13 moves the process to step S106. In step S106, the electrical data of the current (I), voltage (V), and SOC transmitted from the charger 12 to the cloud is obtained.

In step S107, the temperature of the battery 15 in the non-operating state of the monitoring unit 16 is estimated. Specifically, the temperature of the battery 15 in the non-operating state of the monitoring unit 16 is estimated based on the electrical data and the environmental data. Specifically, the electrical data includes the current (I), voltage (V), and SOC, which are obtained in step S106, and the temperature (T) of the battery 15 measured by the monitoring unit 16 in operation at times immediately preceding and subsequent to the non-operating state. The environmental data includes the outside temperature (TE) outside the mobile object 11, which is obtained by the outside temperature sensor 17. After that, the estimating unit 13 moves the process to step S113.

When it is determined in step S105 that the electrical data is not obtainable from the charger 12, the estimating unit 13 moves the process to step S108. In step S108, it is determined whether a change in the SOC of the battery 15 in the operating state of the monitoring unit 16 between a time immediately preceding transition to the non-operating state and a time immediately subsequent to transition from the non-operating state is equal to or greater than a predetermined value. That is, the estimating unit 13 estimates the charge and discharge state of the battery 15 in the non-operating state of the monitoring unit 16 based on the SOC at a time just before the monitoring unit 16 transitions from the operating state to the non-operating state and the SOC at a time just after the monitoring unit 16 transitions back to the operating state from the non-operating state. Thereby, it is determined whether the battery 15 is naturally discharged while the mobile object 11 is parked or the battery 15 is intentionally charged or discharged.

The predetermined value is set to a value larger than an estimation error of the SOC of the battery 15. Therefore, in step S108, it is determined whether the difference between the SOC immediately before the monitoring unit 16 transitions to the non-operating state and the SOC immediately after the monitoring unit 16 transitions back from the non-operating state is equal to or greater than the predetermined value. If it is determined that the SOC difference is equal to or greater than the predetermined value, the process proceeds to step S109.

Naturally, it is expected that the difference between the SOC immediately before the monitoring unit 16 transitions to the non-operating state and the SOC immediately after the monitoring unit 16 transitions back from the non-operating state (i.e., the SOC when the operation begins) will increase in proportion to time, even if the battery 15 is simply discharging naturally. Thus, the predetermined value may be determined based on time as well as the estimation error of the SOC. Furthermore, the degree of change in the SOC also changes depending on the temperature of the external environment. Therefore, the above-mentioned predetermined value may be determined according to the temperature of the battery 15 (i.e., the outside temperature). In this way, the predetermined value is not limited to a fixed value, and may be a variable value that changes depending on environmental changes. The estimation error of the SOC includes, for example, measurement errors contained in the detection results from various sensors used to calculate the SOC.

In step S109, it is determined whether the charge and discharge state of the battery 15 can be obtained. This is determined, for example, by checking whether a charge and discharge operation signal of the battery 15 is stored in the cloud during the non-operation state of the monitoring unit 16. The charge and discharge operation signal is a signal indicating that the battery 15 is being charged or discharged during the non-operation state of the monitoring unit 16. If the charge and discharge state of the battery 15 can be obtained, the estimating unit 13 moves the process to step S110.

In step S110, the estimating unit 13 estimates the voltage, current, SOC, and temperature of the battery 15 in the non-operating state of the monitoring unit 16. Specifically, the estimating unit 13 estimates the voltage, current, SOC, and temperature of the battery 15 in the non-operating state of the monitoring unit 16 based on the electrical data, the environmental data, and the charge and discharge state data of the battery 15. Specifically, the electrical data includes the voltage (V), temperature (T), and the SOC at times immediately before the monitoring unit 16 transitions to the non-operating state and immediately after the monitoring unit 16 transitions back from the non-operating state, which are obtained by the monitoring unit 16 in the operating state. The environmental data includes the outside temperature (TE) outside the mobile object 11, which is obtained by the outside temperature sensor 17.

The voltage of the battery 15 in the non-operating state of the monitoring unit 16 is estimated based on the voltage (V) at times immediately before the monitoring unit 16 transitions to the non-operating state and immediately after the monitoring unit 16 transitions back from the non-operating state, which are obtained by the monitoring unit 16 in the operating state. The temperature of the battery 15 during the non-operating state of the monitoring unit 16 is estimated based on the temperature (T) at times immediately before the monitoring unit 16 transitions to the non-operating state and immediately after the monitoring unit 16 transitions back from the non-operating state, which are obtained by the monitoring unit 16 in the operating state and the outside temperature (TE) outside the mobile object 11 during the non-operating state of the monitoring unit 16.

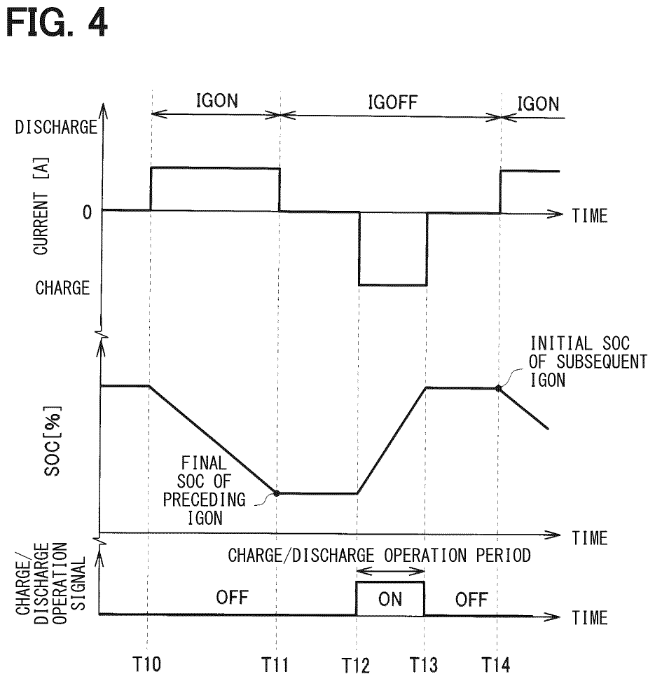

The current and SOC of the battery 15 in the non-operating state of the monitoring unit 16 are estimated as follows. First, as shown in FIG. 4, after the IGON period during which the monitoring unit 16 is operating, the IGOFF period during which the monitoring unit 16 is not operating occurs. After the IGOFF period, the IGON period occurs again.

Then, during the IGOFF period, the charge and discharge operation signal is turned on. Thus, when the IGON period occurs again, the timing at which the battery 15 is charged or discharged during the IGOFF period can be known. That is, current flows through the battery 15 and the SOC fluctuates while the charge and discharge operation signal is ON. Therefore, the current value and the SOC during the IGOFF period can be estimated in accordance with the timing at which the battery 15 is charged or discharged during the IGOFF period.

The example shown in FIG. 4 is a case where the charge and discharge operation signal includes charging information. The IGON period during which the monitoring unit 16 operates begins from the time T10. This causes the battery 15 to be discharged, thereby decreasing the SOC. For example, the monitoring unit 16 samples data every second, and the obtaining unit 18 collectively transmits the data to the estimation unit 13 every 10 seconds. As a result, the SOC during the IGON period is stored in the cloud.

At the time T11, the monitoring unit 16 transitions from the operating state to the non-operating state. That is, the IGOFF period begins. The SOC immediately before the monitoring unit 16 transitions to the non-operating state, i.e., the final SOC of the previous IGON period, is stored in the cloud. The final SOC of the previous IGON period is the SOC calculated by the monitoring unit 16.

The final SOC of the previous IGON period may be calculated based on data obtained at the last sampling timing of the obtaining unit 18, or based on data obtained at an earlier timing than the last sampling timing of the obtaining unit 18. In addition, the final SOC of the previous IGON period may be calculated based on multiple pieces of data obtained by the obtaining unit 18 at different timings near the last sampling timing.

At time T12, charging of the battery 15 starts. This causes the charge and discharge operation signal to be turned on. In addition, the SOC of the battery 15 increases.

At time T13, the charging of the battery 15 is completed. This causes the charge and discharge operation signal to be turned off. The period from time T12 to time T13 during which the charge and discharge operation signal is turned on corresponds to a charge and discharge operation period.

At time T14, the monitoring unit 16 transitions from the non-operating state to the operating state, thus the IGON period starts again. The SOC immediately after the monitoring unit 16 transitions back from the non-operating state, that is, the initial SOC of the subsequent IGON period is stored in the cloud. The initial SOC of the subsequent IGON period is the SOC calculated by the monitoring unit 16.

The initial SOC of the subsequent IGON period may be calculated based on data obtained at an initial sampling timing by the obtaining unit 18, or multiple pieces of data obtained by the obtaining unit 18 at different timings near the initial sampling timing.

After time T14, the current and SOC of the battery 15 during the IGOFF period, i.e., when the monitoring unit 16 is not operating, are estimated.

The current and SOC of the battery 15 in the non-operating state of the monitoring unit 16 are estimated as follows. First, the timing at which the battery 15 is charged or discharged is determined based on the charge and discharge operation signal. That is, the charge and discharge operation period of the battery 15 is obtained. Also, the current value flowing for the change in the SOC during the charge and discharge operation period from the final SOC of the previous IGON period to the initial SOC of the subsequent IGON period is estimated.

The current value is estimated through calculation as follows: estimated current [A]=(the final SOC of the previous IGON period [%]−the initial SOC of subsequent IGON period [%])/100×full charge capacity [Ah]/charge and discharge operation period [h]. It is assumed that the current value estimated in this way continues to flow during the charge and discharge operation period.

The SOC during the IGOFF period is calculated by integrating the above estimated current value. That is, when Δt represents the calculation processing cycle, the estimated SOC is calculated by the following Equation 1.

$$SOC ( t ) [ \% ] = SOC ( t - Δ t ) [ \% ] + estimated current [ A ] / full charge capacity [ Ah ] \times Δ t ( h ) \qquad ( Equation 1 )$$

In this manner, the current and the SOC in the non-operating state of the monitoring unit 16 are estimated.

Similarly, when the charge and discharge operation signal includes discharge information, the current value flowing for the change in the SOC is estimated, and the SOC is calculated by integrating the estimated current value. As described above, the voltage, current, SOC, and temperature of the battery 15 when the monitoring unit 16 is not operating are estimated in step S110, and then the estimating unit 13 moves the process to step S113.

In step S109, when the charge and discharge state of the battery 15 is not obtainable, the estimating unit 13 moves the process to step S111. In step S111, the voltage, current, SOC, and temperature of the battery 15 when the monitoring unit 16 is not operating are estimated. Specifically, the voltage (V), temperature (T), and SOC are estimated based on the electrical data and the environmental data. Specifically the electrical data includes the voltage (V), temperature (T), and SOC at times immediately before the monitoring unit 16 transitions to the non-operating state and immediately after the monitoring unit 16 transitions back from the non-operating state, which are obtained by the monitoring unit 16 in the operating state. The environmental data includes the outside temperature (TE) outside the mobile object 11, which is obtained by the outside temperature sensor 17.

Here, in step S111, unlike step S110, there is no information regarding charge and discharge of the battery 15 during the IGOFF period, so it is not clear whether the battery 15 has been charged or discharged during the IGOFF period. Thus, it is determined whether charging or discharging has been performed based on the magnitude relationship of the SOC. That is, if the final SOC of the previous IGON period is smaller than the initial SOC of the subsequent IGON period, it is determined that charging has been performed. If the final SOC of the previous IGON is greater than the initial SOC of the subsequent IGON period, it is determined that discharging has been performed.

In addition, it is not clear at which timing during the IGOFF period the battery 15 was charged or discharged. For example, there are cases where charging and discharging of the battery 15 starts immediately after transition from the IGON period to the IGOFF period.

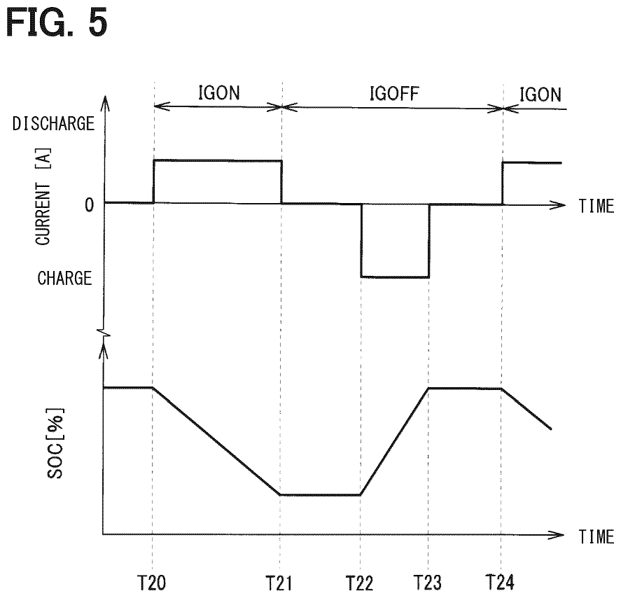

Alternatively, as shown in FIG. 5, the IGON period starts at time T20 and transitions to the IGOFF state at time T21. The charging of the battery 15 may start at time T22 after a certain period has passed from time T21 and lasts until time T23. The IGOFF period switches to the IGON period at time T24.

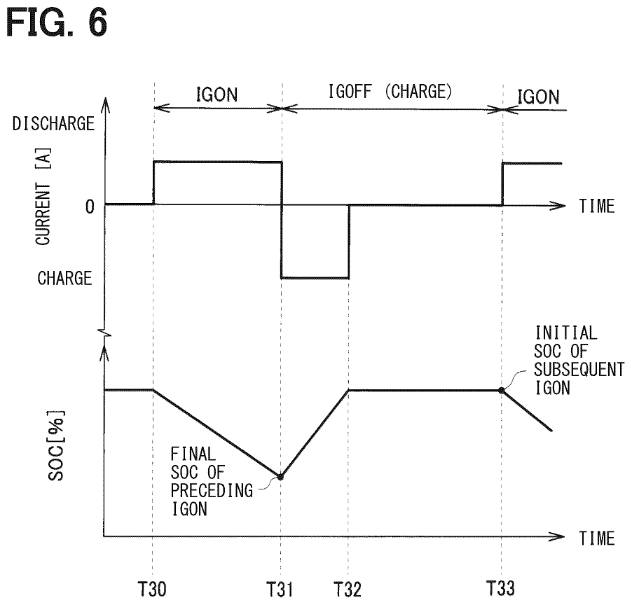

Then, as shown in FIG. 6, for estimating the charge and discharge current of the battery 15, it is assumed that the IGON period starts at time T30, and charge and discharge of the battery 15 starts at time T31, which is the timing immediately after the IGON period switches to the IGOFF period, because time T31 is the most likely timing for starting the charge and discharge. The example shown in FIG. 6 is a case where charging has been performed.

First, the final SOC of the previous IGON period is stored in the cloud just before transition to the IGOFF period. Then, charging starts at time T31 immediately after transition to the IGOFF period. As a result, the SOC of the battery 15 increases. Furthermore, charging ends at time T32. Thereafter, the IGON period restarts at time T33.

After time T33, the initial SOC of the subsequent IGON period is calculated from the measured value of the Open Circuit Voltage (OCV) of the battery 15 and stored in the cloud. The initial SOC of the subsequent IGON period is obtained based on, for example, an OCV-SOC curve. After time T33, the current and the SOC of the battery 15 during the IGOFF period are estimated.

The current and SOC of the battery 15 during the non-operating state of the monitoring unit 16 are estimated as follows. First, since the charging current value cannot be measured, a predetermined current value is used as an estimated current. The predetermined current value is expressed as equation 2. The predetermined current value is determined for each vehicle model of the mobile object 11.

$$predetermined current value [ A ] = charger rated power [ k W ] / battery pack rated voltage [ V ] \qquad ( Equation 2 )$$

As the charger rated power, a general charger rated power is used. The charger rated power is, for example, 6 kW. The battery pack rated voltage is set for each model of the mobile object 11. The battery pack rated voltage is, for example, 300 V.

The SOC is calculated by integrating the estimated current value. That is, it is calculated using the predetermined current value and the above-mentioned Equation 1. It is also assumed that the estimated current continues to flow until the SOC calculated by Equation 1 reaches the initial SOC of the subsequent IGON period calculated from the measured OCV value. Then, it is assumed that, when the SOC calculated by Equation 1 reaches the initial SOC of the subsequent IGON period calculated from the measured OCV value, the flow of current is stopped. This allows an estimation of the SOC that has changed due to charging from time T31 to time T32.

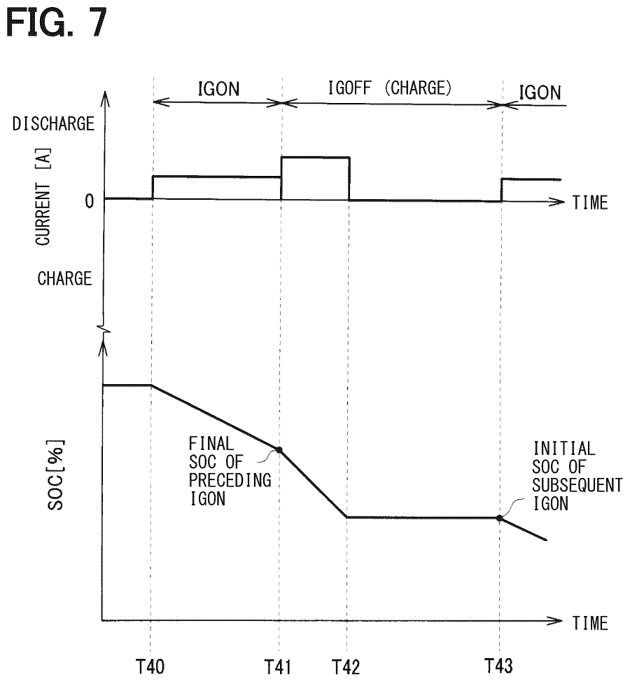

As shown in FIG. 7, when the battery 15 is discharged, it is assumed that the discharge of the battery 15 is started at time immediately after transition to the IGOFF period, which is the most likely timing for starting discharging, for estimating discharged current of the battery 15.

In the example shown in FIG. 7, the IGON period starts at time T40. Discharge begins at this time T40. After a period of time has elapsed, at time T41, the IGON period switches to the IGOFF period. At this time, the battery 15 is discharged in a manner different from that during the IGON period. The discharge during the IGON period may be a natural discharge. At time T41 just before transition to the IGOFF period, the final SOC of the previous IGON period is stored in the cloud.

As the battery 15 is discharged from time T41, the SOC of the battery 15 decreases. The discharge ends at time T42. Thereafter, the IGON period restarts at time T43. As in the case of charging, the initial SOC of the subsequent IGON period is calculated from the measured OCV value of the battery 15 and stored in the cloud.

The method of estimating the current and the SOC of the battery 15 when the monitoring unit 16 is not operating is the same as in the case of charging. That is, the SOC is calculated by accumulating the predetermined current value. Also, it is assumed that, when the SOC calculated by Equation 1 reaches the initial SOC of the subsequent IGON period, which is calculated from the measured OCV value, the flow of current is stopped. This allows an estimation of the change in the SOC due to discharging from time T41 to time T42.

It should be noted that the charge and discharge current and the SOC of the battery 15 may be estimated without assuming that the battery 15 is charged or discharged from the timing immediately after the transition to the IGOFF period. For example, the charge and discharge current and the SOC of the battery 15 may be estimated on the assumption that the battery 15 is charged or discharged after a certain period has elapsed since the start of the IGOFF period.

As described above, after the voltage, current, SOC, and temperature of the battery 15 when the monitoring unit 16 is not operating are estimated in step S111, the estimating unit 13 moves the process to step S113.

If it is determined in step S108 that the difference between the SOC at a time immediately before the monitoring unit 16 transitions to the non-operating state and the SOC at a time immediately after the monitoring unit 16 transitions back from the non-operating state is less than the predetermined value, the estimating unit 13 moves the process to step S112. In this case, the mobile object 11 is left unattended.

In step S112, the temperature of the battery 15 when the monitoring unit 16 is not operating is estimated. Specifically, the temperature of the battery 15 when the monitoring unit 16 is not operating is estimated based on the electrical data and the environmental data. Specifically, the electrical data includes the temperature (T) at times immediately before the monitoring unit 16 transitions to the non-operating state and immediately after the monitoring unit 16 transitions back from the non-operating state, which are obtained by the obtaining unit 18 from the monitoring unit 16 in operation. The environmental data includes the outside temperature (TE) outside the mobile object 11, which is obtained by the outside temperature sensor 17. In addition, when the vehicle is left unattended, the current is 0 A, the voltage does not change, and the SOC does not change. After that, the estimating unit 13 moves the process to step S113.

In step S113, a battery degradation diagnosis is performed. That is, the estimating unit 13 estimates the degradation degree of the battery 15 based on the charge and discharge state of the battery 15 and the temperature of the battery 15.

Specifically, the change in the degradation degree of the battery 15 is obtained based on the data acquired in steps S107, and S110 to S112. Furthermore, the estimating unit 13 recognizes the current degradation degree of the battery 15 by integrating the change in the degradation degree of the battery 15 from the initial state of the battery 15 up to the present. Therefore, the degradation degree of the battery 15 is updated by adding the obtained change in the degradation to the degradation degree of the battery 15 so far.

The degradation degree of the battery 15 in present disclosure reflects both the degradation of the battery 15 in the operating state of the monitoring unit 16 and the degradation of the battery 15 in the non-operating state of the monitoring unit 16. Thus, the user can know the degradation degree of the battery 15 from the initial state of the battery 15 when the battery 15 is initially installed in the mobile object 11 to the present. This makes it possible to obtain highly accurate degradation diagnosis results for the battery 15. Information relating to the highly accurate degradation diagnosis result of the battery 15 is output to the display 14.

In step S114, the diagnosis result is displayed. For example, a display program is stored in a storage medium provided in a portable information terminal of the user. In this case, the storage medium of the portable information terminal corresponds to the storage medium of the present disclosure.

The display program is an application program that causes the processor of the portable information terminal to display the degradation state of the battery 15. The display program may display on the display 14, the degradation degree of the battery 15 and at least one of the electrical data related to the electrical state of the battery 15 in the operating state of the monitoring unit 16 or the environmental data related to the environment of the battery 15 in the non-operating state of the monitoring unit 16. The display program can cause the display 14 to display, together with the degradation degree of the battery 15, information related to the degradation degree of the battery 15 in the non-operating state of the monitoring unit 16.

The display method may include displaying the degradation degree as a numerical value and displaying a graph showing the change in the degradation degree over time. The graph display may be arranged so that the time interval on the time axis can be freely changed. Alternatively, the history of the battery 15 may be displayed. The degradation degree of the battery 15 estimated when the monitoring unit 16 is operating may be displayed separately from the degradation degree of the battery 15 estimated when the monitoring unit 16 is not operating. This differentiation can be made, for example, by color, brightness, font, etc. This differentiation display enables the user to know the history of the estimation of the degradation degree of the battery 15.

As described above, in this embodiment, the estimating unit 13 estimates the degradation degree of the battery 15 when the monitoring unit 16 is not operating, based on the electrical data and the environmental data. Thus, the user can know the degradation degree of the battery 15 when the monitoring unit 16 is not operating.

The obtaining unit 18 may obtain individual information of the battery 15. The estimating unit 13 may perform individual authentication of the battery 15 by comparing the authentic individual information of the battery 15 with the individual information of the battery 15 obtained by the obtaining unit 18. The estimating unit 13 may store the authentic individual information of the battery 15 in advance, or may obtain the authentic individual information of the battery 15 by accessing a database in which the authentic individual information of the battery 15 is stored.

The individual information of the battery 15 is obtained in step S102 of FIG. 3. The comparison of the individual information of the battery 15 is performed in step S113 of FIG. 3. The individual information of the battery 15 may be obtained and compared in steps different from the steps shown in FIG. 3.

As described above, the battery management system 10 may have an authentication function. For example, individual authentication is required in a battery-exchangeable mobile object 11. The individual authentication realizes identification between genuine and non-genuine batteries.

The battery 15 mounted on the battery-exchangeable mobile object 11 may be equipped with a memory. In this case, the electrical data and the environmental data may be stored in the memory installed in the battery 15. The memory of the battery 15 corresponds to a memory that stores electrical data relating to the electrical state of the battery 15 in the operating state of the monitoring unit 16, and environmental data relating to the environment of the battery 15 in the non-operating state of the monitoring unit 16.

When the memory of the battery 15 serves as such memory, the battery 15 stores, in the memory area, electrical data at times immediately before the monitoring unit 16 transitions from the operating state to the non-operating state and immediately after the monitoring unit 16 transitions from the non-operating state to the operating state, and sequential environmental data in the non-operating state of the monitoring unit 16. The electrical data includes the SOC of the battery 15 and the environmental data includes the outside temperature (TE) outside the mobile object 11.

The acquisition of electrical data of the battery 15 when the monitoring unit 16 is not operating is not limited to being done by the charger 12. For example, by providing a current sensor for energizing the power line connecting the charger 12 to the switchboard, data such as the energizing current of the mobile object 11 can be obtained.

### Second Embodiment

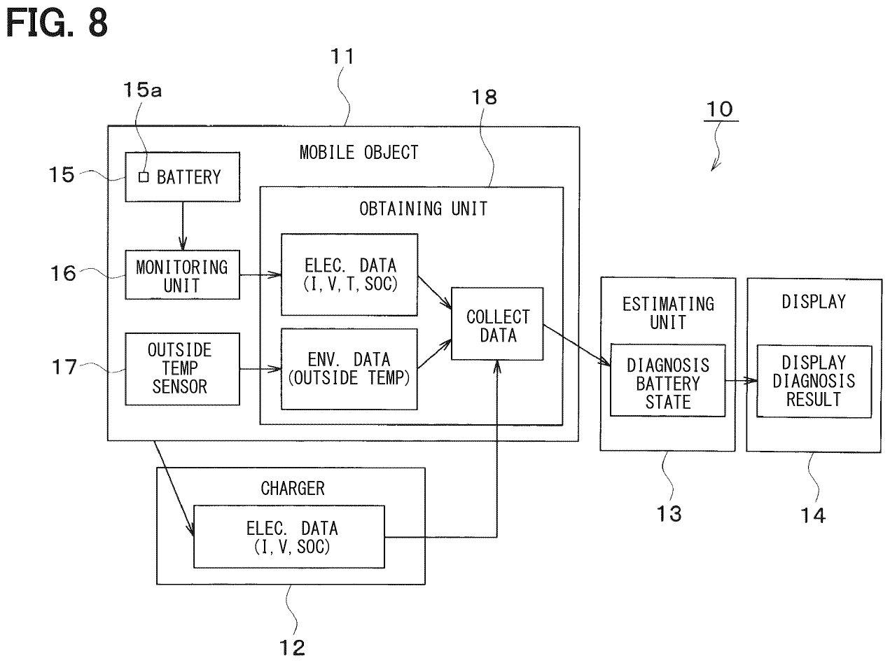

In the present embodiment, portions different from those of the first embodiment will be mainly described. As shown in FIG. 8, the electrical data obtained by the charger 12 is transmitted to the estimating unit 13 via the obtaining unit 18 of the mobile object 11. The charger 12 outputs the electrical data to the obtaining unit 18 of the mobile object 11 using a communication means such as short-range wireless communication. The obtaining unit 18 outputs the electrical data obtained from the charger 12 in addition to the electrical data obtained from the monitoring unit 16 and the environmental data obtained from the outside temperature sensor 17 to the estimating unit 13.

### Third Embodiment

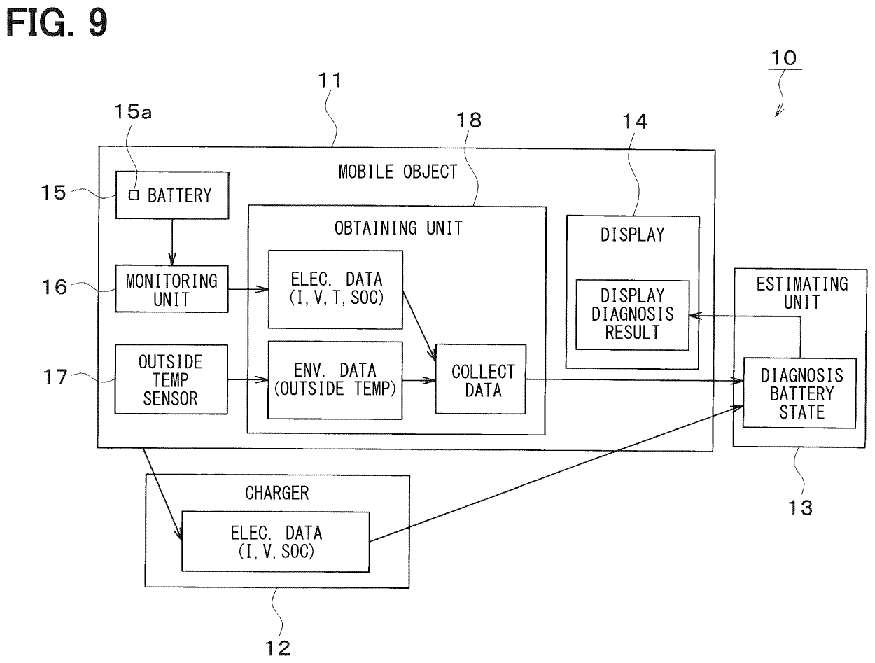

In the present embodiment, portions different from those of the first and second embodiments will be mainly described. As shown in FIG. 9, the display 14 is provided on the mobile object 11. That is, the mobile object 11 includes a storage medium storing the display program. The display 14 receives information on the battery diagnosis results from the estimating unit 13 in the cloud and displays the information.

The display 14 may be a screen such as a navigation panel or a meter panel. Thus, the display program may be stored in an on-board device for navigation of the mobile object 11 or an on-board device for an instrument panel.

### Fourth Embodiment

In the present embodiment, portions different from those of the first to third embodiments will be mainly described. It is not always necessary that the outside temperature sensor 17 directly measures the outside temperature (TE) outside the mobile object 11. The environment information may be any information equivalent to the outside temperature (TE) outside the mobile object 11.

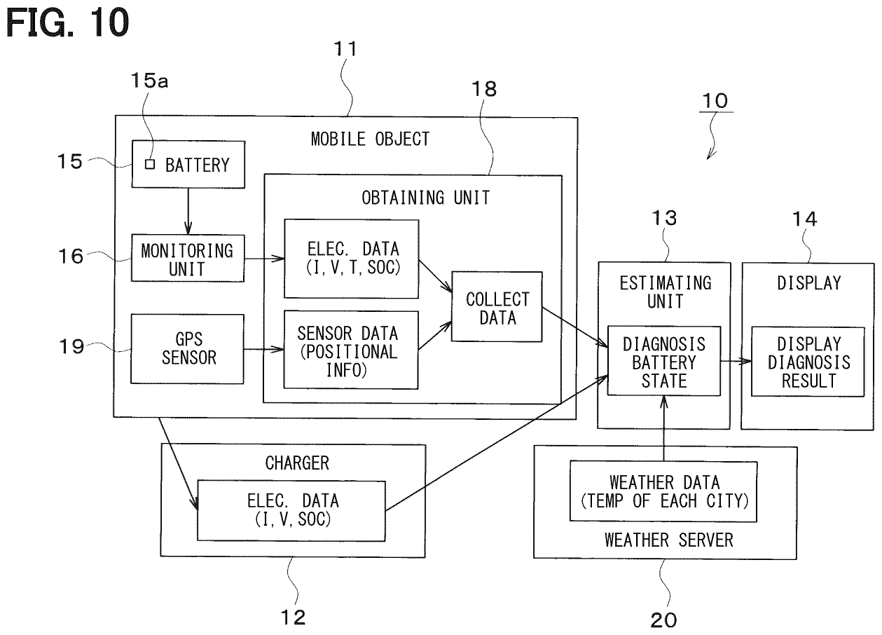

In this embodiment, as shown in FIG. 10, the mobile object 11 has a Global Positioning System (GPS) sensor 19. The GPS sensor 19 acquires information on the current location of the mobile object 11. The obtaining unit 18 collects position information of the mobile object 11 from the GPS sensor 19 as sensor data and outputs it to the estimating unit 13.

The estimating unit 13 obtains, as the environmental data, current weather data for the current location of the mobile object 11 from a weather server 20 storing weather data. The weather server 20 stores temperature data for each city. The estimating unit 13 employs the current temperature data of the mobile object 11 as the outside temperature (TE) of the mobile object 11. The estimating unit 13 estimates the degradation degree of the battery 15 based on the obtained temperature data.

The present disclosure is not limited to the above-described embodiments, and can be variously modified as follows within the scope that does not deviate from the gist of the present disclosure.

For example, the estimating unit 13 may be provided in the mobile object 11. In other words, the degradation degree of the battery 15 may be diagnosed inside the mobile object 11 rather than outside the mobile object 11.

The battery management system 10 may be applied to a small mobile object 11 like a small drone, such as an electric Vertical Take-Off and Landing aircraft (i.e., eVTOL), without being limited to larger mobile objects 11 such as electric vehicles. The electric vehicle needs to be charged, for example, once every three days. In contrast, the charging frequency of the eVTOL is higher than that of the electric vehicle, and for example, nine times a day. Thus, the transition frequency between the operating state and the non-operating state of the monitoring unit 16 is high in the eVTOL. Therefore, the diagnosis of the degradation degree during the non-operating state of the monitoring unit 16 is highly effective for the eVTOL.

The storage medium that stores the display program is not limited to be provided in the mobile object 11 or a portable information terminal to which the display program is downloaded, but may be provided in a server that provides the display program to the mobile object 11 or the portable information terminal.

The mobile object 11, the estimating unit 13, and the display 14 described in the embodiments each have a non-transitory tangible storage medium that non-temporarily stores data and programs that can be read by a computer or a processor. The non-transitory tangible storage medium includes a volatile memory and a non-volatile memory. The non-transitory tangible storage medium stores input information and the results of arithmetic operations performed by the computer or processor. The non-transitory tangible storage medium stores various programs and various reference values for the computer or processor to perform arithmetic operations. It should be noted that the charger 12 may include the non-transitory tangible storage medium.

The embodiments can be combined. For example, by combining the first and second embodiments, the charger 12 can transmit electrical data to the estimating unit 13 directly or via the mobile object 11 depending on the situation.

Alternatively, by combining the first and third embodiments, the degradation degree of the battery 15 can be displayed on both the screen of the portable information terminal and the screen of the mobile object 11. Alternatively, by combining the first and fourth embodiments, the outside temperature (TE) outside the mobile object 11 can be obtained from the outside temperature sensor 17 or the weather server 20, or both of them.

In addition, a combination of the second embodiment and the third embodiment, a combination of the second embodiment and the fourth embodiment, and a combination of the third embodiment and the fourth embodiment are also possible. It is also possible to combine three or more embodiments.

Although the present disclosure has been described in accordance with the examples, it is understood that the disclosure is not limited to such examples or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

1. A battery management system for a battery in a mobile object, the battery management system comprising:
an obtaining unit configured to obtain:
electrical data related to an electrical state of the battery in an operating state of a monitoring unit that monitors the battery; and
environmental data related to an environment of the battery in a non-operating state of the monitoring unit;
an estimating unit configured to estimate, based on the electrical data and the environmental data, a degradation degree of the battery in the non-operating state of the monitoring unit; and
a display configured to display the estimated degradation degree of the battery, wherein
the electrical data includes:
a first SOC of the battery at a time before the monitoring unit transitions from the operating state to the non-operating state; and
a second SOC of the battery at a time after the monitoring unit transitions from the non-operating state to the operating state, and
the environmental data includes an outside temperature outside the mobile object in the non-operating state of the monitoring unit,
the estimating unit is configured to:
estimate a charge and discharge state of the battery in the non-operating state of the monitoring unit based on the first SOC and the second SOC;
estimate a temperature of the battery in the non-operating state of the monitoring unit based on the outside temperature in the non-operating state; and
estimate the degradation degree of the battery in the non-operating state based on the estimated charge and discharge state and the estimated temperature of the battery.

2. The battery management system according to claim 1, wherein
the obtaining unit is configured to obtain individual information of the battery,
the estimating unit is configured to authenticate the battery by comparing the obtained individual information of the battery obtained by the obtaining unit with an authentic individual information of the battery.

3. A memory included in the battery management system according to claim 1, the memory being configured to store:
the electrical data related to the electrical state of the battery in the operating state of the monitoring unit; and
the environmental data related to the environment of the battery in the non-operating state of the monitoring unit.

4. The memory according to claim 3, wherein
the electrical data includes:
electrical data at a time before the monitoring unit transitions from the operating state to the non-operating state; and
electrical data at a time after the monitoring unit transitions from the non-operating state to the operating state, and
the environmental data includes sequential environmental data in the non-operating state of the monitoring unit.

5. The memory according to claim 4, wherein p1 the electrical data includes a SOC of the battery, and
the environmental data includes an outside temperature outside the mobile object.

6. A display method used in the battery management system according to claim 1, the display method comprising
displaying, on a display, the degradation degree of the battery and at least one of the electrical data related to the electrical state of the battery in the operating state of the monitoring unit or the environmental data related to the environment of the battery in the non-operating state of the monitoring unit.

7. A storage medium included in the battery management system according to claim 1, the storage medium storing a display program that is configured to cause a processor to
display, on a display, the degradation degree of the battery and at least one of the electrical data related to the electrical state of the battery in the operating state of the monitoring unit or the environmental data related to the environment of the battery in the non-operating state of the monitoring unit.

8. The storage medium according to claim 7, wherein
the storage medium is provided in a portable information terminal.

9. The storage medium according to claim 7, wherein
the storage medium is provided in the mobile object.
